(19) United States
(12) Patent Application Publication
(10) Pub. No.: US 2024/0234238 A1
(43) Pub. Date: Jul. 11, 2024

(54) POWER MODULE THERMAL MANAGEMENT

(71) Applicant: GM GLOBAL TECHNOLOGY OPERATIONS LLC, DETROIT, MI (US)

(72) Inventors: Chandra S. Namuduri, Troy, MI (US); Rashmi Prasad, Troy, MI (US)

(21) Appl. No.: 18/150,379

(22) Filed: Jan. 5, 2023

(51) Int. Cl. H01L 23/373; H01L 21/48; H01L 23/15; H01L 23/38; H01L 23/498

(52) U.S. Cl. CPC H01L 23/3735; H01L 21/4846; H01L 21/4882; H01L 23/15; H01L 23/38; H01L 23/49833; H01L 23/49844; H01L 24/32

(57) ABSTRACT

Aspects of the disclosure include a power module having enhanced thermal management. An exemplary power module can include a direct bond copper (DBC) substrate having a top copper layer, a bottom copper layer, and a dielectric layer between the top copper layer and the bottom copper layer. The power module includes a thin-film thermoelectric cooler (TFTEC) having a thermoelectric film positioned between a top insulator and a bottom insulator. One or more dies are positioned over the DBC substrate and the TFTEC and a controller is configured to adjust a thermoelectric device current of the TFTEC responsive to a temperature of the one or more dies.

### INTRODUCTION

The subject disclosure relates to power electronics modules, and particularly to power module thermal management.

High-density power electronics modules are used in a variety of applications, ranging from power delivery and electronics support in electric vehicles (EVs) and hybrid electric vehicles (HEVs) to control and power systems in industrial, marine, aerospace, locomotive, and utility applications. The ongoing development of high-density power electronics modules has placed increasingly large strains on the thermal management systems tasked with cooling these powered semiconductor devices. Modern silicon-based power electronics devices, for example, are capable of dissipating up to 500 W/cm². Natural and forced air cooling systems can only handle heat fluxes up to a few W/cm², while liquid cooling plates can achieve heat fluxes on the order of several tens of W/cm².

Double sided and actively cooled power modules can manage heat fluxes that exceed 600 W/cm² and are increasingly relied upon for this function. The planar cooled power module package typically includes one or more upper power switch dies and one or more lower power switch dies sandwiched between two direct bond copper (DBC) substrates (the so-called double-sided cooled power module). Simpler, single-sided cooled power modules include a single DBC, but otherwise function similarly. In many configurations, cold plates (often with pin fins on one side) are directly bonded to an outside surface of the DBC substrate(s).

### SUMMARY

In one exemplary embodiment a power module for enhanced thermal management can include a direct bond copper (DBC) substrate having a top copper layer, a bottom copper layer, and a dielectric layer between the top copper layer and the bottom copper layer. The power module includes a thin-film thermoelectric cooler (TFTEC) having a thermoelectric film positioned between a top insulator and a bottom insulator. One or more dies are positioned over the DBC substrate and the TFTEC and a controller is configured to adjust a thermoelectric device current of the TFTEC responsive to a temperature of the one or more dies.

In some embodiments, the one or more dies each include one of an Insulated Gate Bipolar Transistor (IGBT), an anti-parallel diode, a Silicon Carbide (SiC) MOSFET die, a Gallium Nitride (GaN) High Electron Mobility Transistor (HEMT) die, or a vertical GaN Junction Field Effect Transistor (JFET) die.

In addition to one or more of the features described herein, in some embodiments, the power module further includes a cold plate (heat sink) coupled to one of the DBC substrate and the TFTEC.

In some embodiments, the dielectric layer of the DBC substrate includes at least one of a ceramic material, silicon nitride (Si₃N₄), aluminum-oxide (Al₂O₃), and aluminum-nitride (AlN). In some embodiments, the thermoelectric film of the TFTEC includes a nano-composite thermoelectric film of Bi₂Te₃, although other high performance Peltier effect materials are within the contemplated scope of this disclosure.

In some embodiments, a bottom surface of the one or more dies is secured to the top copper layer of the DBC substrate. In some embodiments, a bottom surface of the one or more dies is secured to the top insulator of the TFTEC.

In another exemplary embodiment a vehicle includes an electric motor and a power module coupled to the electric motor. The power module can include a DBC substrate having a top copper layer, a bottom copper layer, and a dielectric layer between the top copper layer and the bottom copper layer. The power module includes a TFTEC having a thermoelectric film positioned between a top insulator and a bottom insulator. One or more dies are positioned over the DBC substrate and the TFTEC and a controller is configured to adjust a thermoelectric device current of the TFTEC responsive to a temperature of the one or more dies.

In yet another exemplary embodiment a method for providing a power module having enhanced thermal management can include forming a DBC substrate having a top copper layer, a bottom copper layer, and a dielectric layer between the top copper layer and the bottom copper layer. The method further includes forming a TFTEC having a thermoelectric film positioned between a top insulator and a bottom insulator. One or more dies are positioned over the DBC substrate and the TFTEC. A controller electrically coupled to the one or more dies and the TFTEC adjusts a thermoelectric device current of the TFTEC responsive to a temperature of the one or more dies.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a vehicle configured in accordance with one or more embodiments;

FIG. 2 is a cross-sectional view of a power module in accordance with one or more embodiments;

FIG. 3 is a cross-sectional view of an alternative embodiment of the power module in accordance with one or more embodiments;

FIG. 4 is a cross-sectional view of yet another alternative embodiment of the power module in accordance with one or more embodiments;

FIG. 5 is a block diagram of a thermal management system for a power module configured in accordance with one or more embodiments;

FIG. 6 is a computer system according to one or more embodiments; and

FIG. 7 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

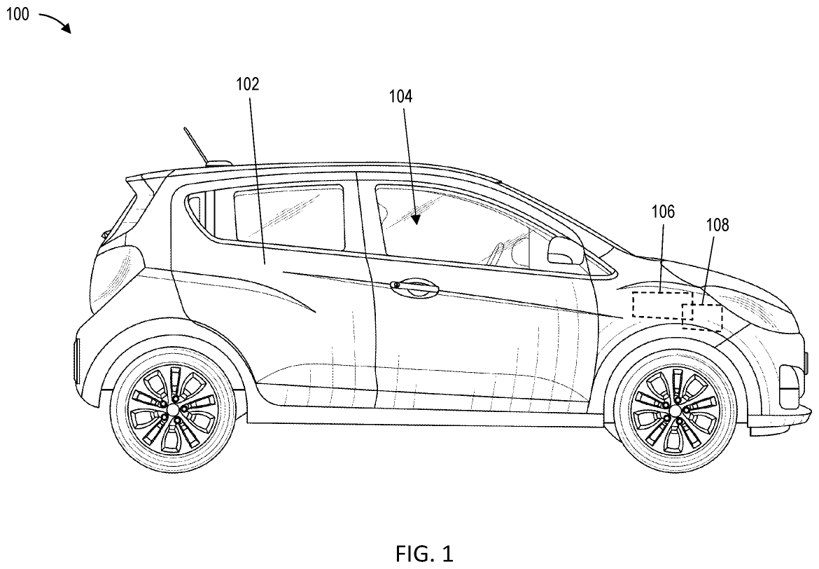

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Within the body 102 are arranged a number of components, including, for example, an electric motor 106 (shown by projection under the front hood). The electric motor 106 is shown for ease of illustration and discussion only. It should be understood that the configuration, location, size, arrangement, etc., of the electric motor 106 is not meant to be particularly limited, and all such configurations (including multi-motor configurations) are within the contemplated scope of this disclosure. As will be detailed herein, the vehicle 100 further includes a power module 108 (shown by projection near the front of the vehicle 100). The power module 108 is shown for ease of illustration and discussion only. It should be understood that the configuration, location, size, arrangement, etc., of the power module 108 is not meant to be particularly limited, and all such configurations (including configurations having a plurality of cooled power modules) are within the contemplated scope of this disclosure.

As discussed previously, high-density power electronics modules, such as those found in electric vehicles (EVs), require powerful thermal management systems. For example, power electronics systems in EVs require running one or more semiconductor chips at a high temperature at peak load to reduce costs and increase power density. Power electronics modules typically include one (single-sided) or two (double-sided) direct bonded copper (DBC) and/or active metal brazing (AMB) substrates coupled between the semiconductor chip and a cold plate (heat sink) for cooling. Silicon carbide (SiC) is increasingly used in DBC substrates due to a unique offering of power efficiency, decreased size, lighter weight, and lower overall cost as compared to silicon-based systems. Unfortunately, large temperature excursions between the heat sink and the junction of the semiconductor chip leads to thermal fatigue and failure in silicon carbide-based power electronics modules. In some cases, silicon carbide-based power electronics modules can be limited in overload capability due to the presence of higher heat flux densities that result in higher temperature junction excursions.

This disclosure introduces a power module that reduces junction temperature excursions. A thin-film thermoelectric cooler (TFTEC) with low thermal resistance and a high coefficient of performance (COP) is incorporated between the cold plate and the semiconductor chip substrate. An electric current or power into the TFTEC is controlled to reduce the temperature excursion at the chip junction depending on the power module load. In some embodiments, the TFTEC includes an ultra thin (˜100 μm or less), nano-composite thermoelectric film.

Power modules constructed in accordance with one or more embodiments offer several technical advantages over prior thermal management solutions. In particular, power modules having integrated high temperature, ultra thin nano-composite thermoelectric films between the power module substrate and the heat sink can effectively lower the junction excursion temperature (ΔT_{JC}) of the chips. The result is a power module having a longer life, reduced failures, and lower losses as compared to power modules lacking TFTEC integration. Other advantages are possible.

For example, in some embodiments, the power input to the TFTEC can be controlled based on the chip current and/or an estimated power dissipation to minimize parasitic loss. In some embodiments, the TFTEC is leveraged to harvest the heat energy from the power module, which can be reused for cooling to improve overall efficiency. Advantageously, power modules with single side or double side integrated TFTEC materials offer a higher COP (e.g., at least 3 to 10) than power modules lacking TFTEC integration.

Power modules constructed in accordance with one or more embodiments offer demonstrably improved reliability—a reduction of the power-semiconductor junction temperature by 10 degrees Celsius results in a roughly 2× improvement in semiconductor reliability. Power modules having integrated TFTECs offer a faster transient response (i.e., on the order of a few milliseconds) as compared to conventional thermal management methods (i.e., on the order of a few seconds). Moreover, power density is increased due to reductions in power device size afforded by the higher efficiencies.

Power modules described herein are enablers for more aggressive power delivery profiles, such as an extended max power mode (short term peak) for the electric motor 106 of FIG. 1. These power modules are also enablers for higher coolant temperature-based single cooling loops in both hybrid electric vehicles (HEVs) and plug-in hybrid electric vehicles (PHEVs). In EVs, HEVs, and PHEVs, for example, the mass, size, and cost of the cooling system is reduced due to the elimination of separate cooling loops for on-board power electronics and motors.

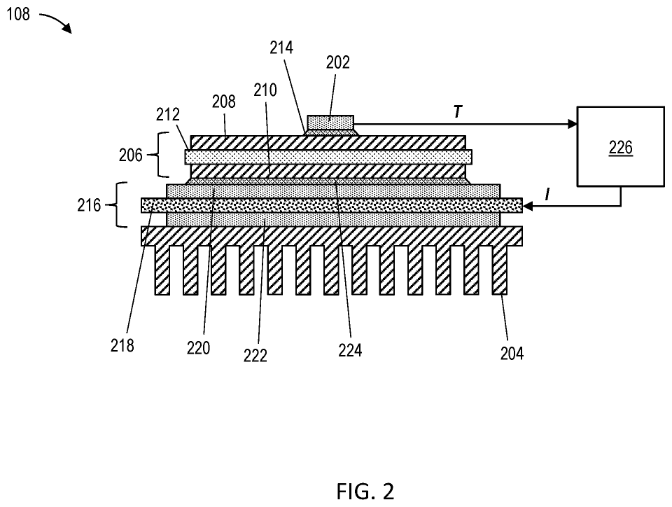

FIG. 2 illustrates a cross-sectional view of a power module 108 in accordance with one or more embodiments. The power module 108 can be included within or coupled to an electric motor (e.g., the electric motor 106 of FIG. 1), although other applications are within the contemplated scope of this disclosure. In some embodiments, the power module 108 includes one or more dies 202 (also referred to as semiconductor chips), a cold plate 204, and a DBC substrate 206 positioned between the dies 202 and the cold plate 204.

The dies 202 can include any of a variety of components, such as, for example, an Insulated Gate Bipolar Transistor (IGBT), an anti-parallel diode, a Silicon Carbide (SiC) MOSFET die, a Gallium Nitride (GaN) High Electron Mobility Transistor (HEMT) die, a vertical GaN Junction Filed Effect Transistor (JFET) die, etc. While shown as having a single die for ease of illustration and discussion, the number, type, and configuration of the dies 202 in the power module 108 is not meant to be particularly limited and all configurations are within the contemplated scope of this disclosure.

The cold plate 204 can be made from any suitable material, such as, for example, metals and metal alloys having high or very high thermal conductivities (e.g., aluminum, copper, and alloys thereof), although more exotic materials, such as thermal interface materials, are within the contemplated scope of the disclosure. The cold plate 204 can include, for example, a bulk body and one or more heat dissipating fins, although other configurations are within the contemplated scope of the disclosure.

In some embodiments, the DBC substrate 206 includes a top copper layer 208, a bottom copper layer 210, and a dielectric layer 212. The dielectric layer 212 can include any suitable DBC base material, such as, for example, thermally conductive, electrically insulating ceramics, silicon nitride (Si₃N₄), aluminum-oxide (Al₂O₃), and/or aluminum-nitride (AlN), although other configurations and materials are possible. In some embodiments, the top copper layer 208 and the bottom copper layer 210 are directly bonded to respective surfaces of the dielectric layer 212. Any suitable bonding technique can be used, for example, active metal brazing.

In some embodiments, an adhesion layer 214 on a bottom surface of the dies 202 secures attachment of the dies 202 to the DBC substrate 206. The adhesion layer 214 can include, for example, solder and/or sintered silver.

In some embodiments, the power module 108 further includes a TFTEC 216. Thin-film thermoelectric coolers leverage the Peltier effect to transfer heat between a main surface (or hot side) and a waste surface (or cold side) in response to a received current. The particular configuration of the TFTEC 216 in a given application is not meant to be particularly limited, and can include, for example, an alternating array of n- and p-type semiconductors (e.g., bismuth telluride, antimony telluride, lead telluride, bismuth selenide, etc.) having complementary Peltier coefficients soldered or otherwise fixed between a pair of plates (e.g., ceramic plates, metal plates, etc.). In some embodiments, the TFTEC 216 is configured to transfer thermal energy between the dies 202 (i.e., the hot side) and the heat sink 204 (i.e., the cold side) upon the application of an electric current I.

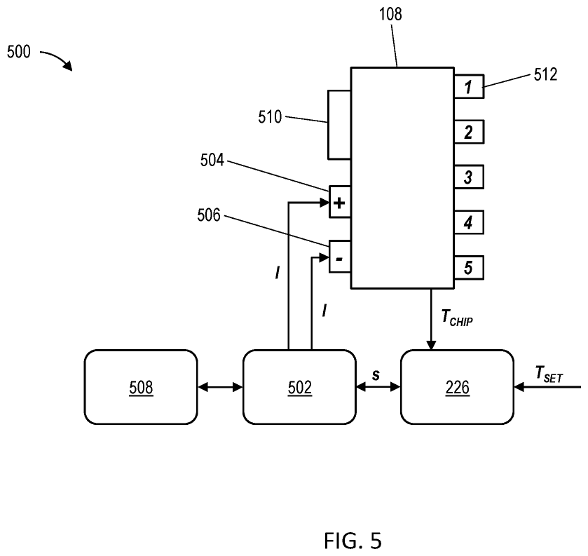

In some embodiments, the TFTEC 216 includes an ultra thin (about ˜100 μm or less), nano-composite thermoelectric film 218. In some embodiments, the thermoelectric film 218 includes, for example, Bi₂Te₃, although other thin film nano-composite materials are within the contemplated scope of this disclosure. In some embodiments, the thermoelectric film 218 is positioned between a top insulator 220 and a bottom insulator 222. The top insulator 220 and the bottom insulator 222 can include a same and/or different insulator materials, such as, for example, a metalized insulator and/or silicon nitride. In some embodiments, the TFTEC 216 and/or the thermoelectric film 218 includes a plurality of TFTEC elements (not separately shown) connected in series and/or in parallel. In some embodiments, the TFTEC elements are electrically coupled to electrical terminals that are isolated from a main power module terminal (refer to FIG. 5). In some embodiments, the thermoelectric film 218 includes a bulk thickness of less than about 100 μm with an active thickness of less than about 20 μm to minimize thermal resistance.

In some embodiments, an adhesion layer 224 on a top surface of the top insulator 220 secures attachment of the TFTEC 216 to the DBC substrate 206. The adhesion layer 224 can include, for example, solder and/or sintered silver. In some embodiments, a bottom surface of the bottom insulator 222 is secured to the cold plate 204 via a thermal interface material (not separately shown).

As further shown in FIG. 2, the power module 108 can include a controller 226. In some embodiments, the controller 226 is communicatively coupled to a thermocouple (not separately shown) positioned in, on, or adjacent the dies 202. In some embodiments, the thermocouple measures a temperature of the dies 202 and sends this signal (“T” in FIG. 2) to the controller 226. The thermocouple can include a pair of materials (e.g., metals) that are joined together, or coupled, for measuring heat. Thermocouples are widely used in a variety of industries due to their accuracy and large operating range of temperatures. Metals used in thermocouples include iron, nickel, copper, chromium, aluminum, platinum, rhodium, and their alloys.

In some embodiments, the controller 226 is configured to initiate heating or cooling measures for the dies 202 based on the signal “T”. The controller 226 is discussed in greater detail with respect to FIG. 5. In some embodiments, the controller 226 is configured to send a control signal to the TFTEC 216. In some embodiments, the control signal is a current (“I” in FIG. 2, sometimes referred to as a thermoelectric device current) applied to one end of the TFTEC 216, thereby effecting a net heating or net cooling of the dies 202 due to the Peltier effect.

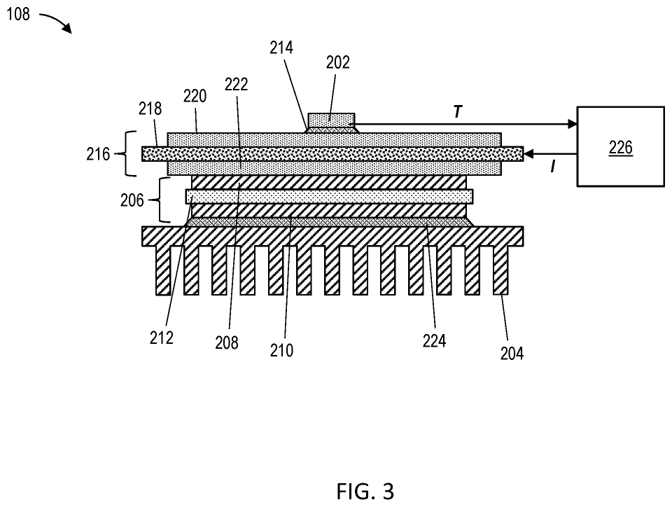

FIG. 3 illustrates a cross-sectional view of an alternative embodiment of the power module 108 in accordance with one or more embodiments. The power module 108 of FIG. 3 is constructed in a similar manner as the power module 108 described previously with respect to FIG. 2, except that the power module 108 depicted in FIG. 3 swaps the relative locations of the TFTEC 216 and the DBC substrate 206. In other words, the embodiment of the power module 108 in FIG. 3 depicts a power module configuration with a TFTEC mounted directly to a semiconductor die (i.e., a direct mount configuration).

In some embodiments, an adhesion layer 214 on a bottom surface of the dies 202 secures attachment of the dies 202 to the TFTEC 216. The adhesion layer 214 can include, for example, solder and/or sintered silver. In some embodiments, an adhesion layer 224 secures the DBC substrate 206 to the cold plate 204. The adhesion layer 224 can include, for example, solder, sintered silver, and/or any other suitable thermal interface materials. In some embodiments, a bottom surface of the bottom insulator 222 is secured to the top copper layer 208 of the DBC substrate 206 via a thermal interface material (not separately shown). Constructing the power module 108 in this manner minimizes cost while achieving required thermal performance.

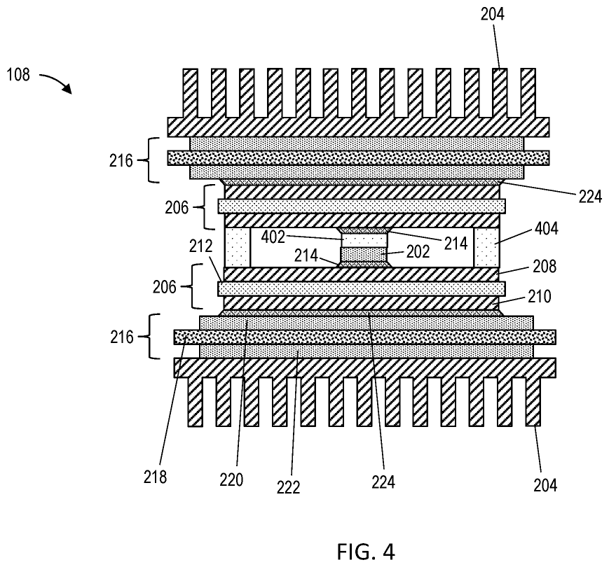

FIG. 4 illustrates a cross-sectional view of yet another alternative embodiment of the power module 108 in accordance with one or more embodiments. The power module 108 of FIG. 4 is constructed in a similar manner as the power module 108 described previously with respect to FIG. 2, except that the power module 108 depicted in FIG. 4 is double-sided. In other words, the embodiment of the power module 108 in FIG. 4 depicts a power module configuration with a pair of TFTECs 216 and DBC substrates 206 mounted on opposite surfaces (top and bottom surfaces) of the semiconductor dies. The controller 226 is omitted for clarity.

In some embodiments, the power module 108 includes one or more optional spacers 402 coupled to the dies 202 and one or more optional spacers 404 between the opposite DBC substrate 206. While not shown, the relative positions of the DBC substrates 206 and the TFTECs 216 can be swapped in a similar manner as described with respect to FIG. 3 (i.e., a double-sided configuration of the embodiment of the power module 108 shown in FIG. 3).

Constructing the power module 108 in this manner allows for double-sided cooling capability as well as a more rigorous control of the top and bottom surface temperatures of the dies 202 (as each surface is serviced by a dedicated cooling assembly). For example, this configuration allows for a conventional liquid cooling on one side of the die while the TFTEC can be applied to the opposite side of the die to maintain the peak junction temperature within limits during peak power demands. The result is a further reduction in the cost of the TFTEC material and additional thermal resistance in the main thermal path.

FIG. 5 depicts a block diagram of a thermal management system 500 for a power module 108 configured in accordance with one or more embodiments. In some embodiments, a controller (e.g., the controller 226 of FIG. 2) is configured to receive a sensor signal (here, T_{CHIP}) from the power module 108. In some embodiments, the sensor signal is a chip temperature (also referred to as a die temperature) of the dies 202, although other signals, such as a power module current and/or an estimated power loss are within the contemplated scope of this disclosure.

In some embodiments, the controller 226 is configured to receive a target temperature signal (here, T_{SET}). In some embodiments, the controller 226 is configured to initiate heating or cooling measures for the dies 202 based on a difference between the signal T_{CHIP} and the signal T_{SET}. For example, heating measures can be initiated when T_{CHIP} is less than T_{SET}, while cooling measures can be initiated when T_{CHIP} is greater than T_{SET}. While not separately shown, the power module 108 can include any number of embedded and/or virtual temperature sensors configured to generate the sensor signal.

In some embodiments, the controller 226 includes or is coupled to a power converter 502. In some embodiments, the power converter 502 is a bidirectional power converter coupled to a positive terminal 504 and a negative terminal 506 of the power module 108. In some embodiments, the controller 226 directs, via a control signal s, the power converter 502 to send a current I to one or both of the positive terminal 504 and the negative terminal 506 of the power module 108, thereby effecting a net heating or net cooling of the dies 202 due to the Peltier effect.

In some embodiments, the thermal management system 500 includes a power supply 508. The power supply 508 can be coupled to the power converter 502. In some embodiments, the power supply 508 and the power converter 502 together define a low voltage DC power source (and sink) having a bidirectionally controlled current capability. As used herein, a “low” voltage DC power source refers to a voltage less than about 50 volts DC (VDC).

In some embodiments, the thermal management system 500 is configured to convert thermal energy from the dies 202 to electrical energy when cooling measures are indicated (according, e.g., to the Peltier effect described previously). In some embodiments, converted electrical energy can be returned to the power supply 508 in a process referred to as DC energy recapture and storage. In some embodiments, this recovered energy is itself used for cooling the dies 202, improving overall thermal efficiency.

As further shown in FIG. 5, in some embodiments, the power module 108 includes a module control connector 510 and one or more main power terminals 512 (here, the main power terminals “1”, “2”, “3”, “4”, and “5”). In some embodiments, the module control connector 510 is connected to one or more external systems (e.g., the electric motor 106 of the vehicle 100 shown in FIG. 1). In some embodiments, the main power terminals 512 are each electrically coupled to a downstream system (e.g., one of the dies 202). In some embodiments, the one or more main power terminals 512 are electrically isolated form the positive terminal 504 and the negative terminal 506 of the power module 108.

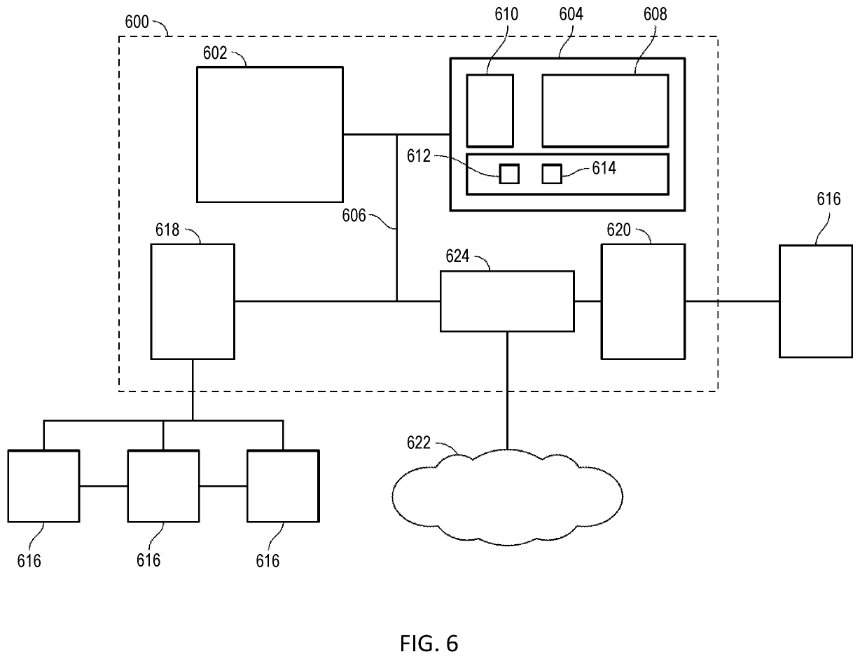

FIG. 6 illustrates aspects of an embodiment of a computer system 600 that can perform various aspects of embodiments described herein. In some embodiments, the computer system 600 can be incorporated within or in combination with a power module (e.g., the power module 108 of FIG. 2). The computer system 600 includes at least one processing device 602, which generally includes one or more processors for performing a variety of functions. More specifically, the computer system 600 can include the logic necessary to direct a current to a TFTEC of a power module.

Components of the computer system 600 include the processing device 602 (such as one or more processors or processing units), a system memory 604, and a bus 606 that couples various system components including the system memory 604 to the processing device 602. The system memory 604 may include a variety of computer system readable media. Such media can be any available media that is accessible by the processing device 602, and includes both volatile and non-volatile media, and removable and non-removable media.

For example, the system memory 604 includes a non-volatile memory 608 such as a hard drive, and may also include a volatile memory 610, such as random access memory (RAM) and/or cache memory. The computer system 600 can further include other removable/non-removable, volatile/non-volatile computer system storage media.

The system memory 604 can include at least one program product having a set (e.g., at least one) of program modules that are configured to carry out functions of the embodiments described herein. For example, the system memory 604 stores various program modules that generally carry out the functions and/or methodologies of embodiments described herein. A module or modules 612, 614 may be included to perform functions related to monitoring and/or control of a power module, such as, for example, determining a current temperature of a die, determining a target temperature of a die, determining a cooling rate required for a die, determining a current required to achieve a targeted cooling rate, etc. The computer system 600 is not so limited, as other modules may be included depending on the desired functionality of the vehicle 100. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. For example, the module(s) can be configured via software, hardware, and/or firmware to stop charging and/or otherwise isolate one or more cells of a battery pack of the vehicle 100.

The processing device 602 can also be configured to communicate with one or more external devices 616 such as, for example, a keyboard, a pointing device, and/or any devices (e.g., a network card, a modem, vehicle ECUs, etc.) that enable the processing device 602 to communicate with one or more other computing devices. Communication with various devices can occur via Input/Output (I/O) interfaces 618 and 620.

The processing device 602 may also communicate with one or more networks 622 such as a local area network (LAN), a general wide area network (WAN), a bus network and/or a public network (e.g., the Internet) via a network adapter 624. In some embodiments, the network adapter 624 is or includes an optical network adaptor for communication over an optical network. It should be understood that although not shown, other hardware and/or software components may be used in conjunction with the computer system 600. Examples include, but are not limited to, microcode, device drivers, redundant processing units, external disk drive arrays, RAID systems, and data archival storage systems, etc.

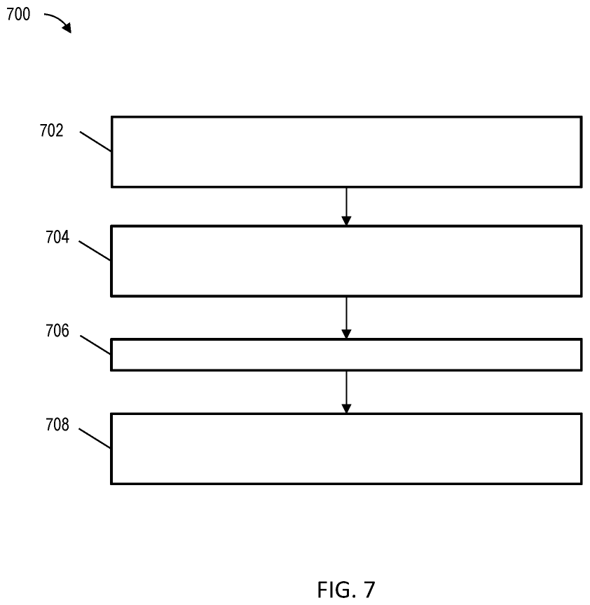

Referring now to FIG. 7, a flowchart 700 for providing a power module for enhanced thermal management is generally shown according to an embodiment. The flowchart 700 is described in reference to FIGS. 1 to 6 and may include additional steps not depicted in FIG. 7. Although depicted in a particular order, the blocks depicted in FIG. 7 can be rearranged, subdivided, and/or combined.

At block 702, a DBC substrate is formed. In some embodiments, the DBC substrate includes a top copper layer, a bottom copper layer, and a dielectric layer between the top copper layer and the bottom copper layer. In some embodiments, the dielectric layer includes at least one of a ceramic material, silicon nitride, aluminum-oxide, and aluminum-nitride.

At block 704, a TFTEC is formed. In some embodiments, the TFTEC includes a thermoelectric film positioned between a top insulator and a bottom insulator. In some embodiments, the thermoelectric film includes a nano-composite thermoelectric film of Bi₂Te₃.

At block 706, one or more dies are positioned over the DBC substrate and the TFTEC. In some embodiments, the one or more dies each include at least one of an IGBT, an anti-parallel diode, a SiC MOSFET die, a GaN HEMT die, or a vertical GaN JFET die.

In some embodiments, a bottom surface of the one or more dies is secured to the top copper layer of the DBC substrate (refer to FIG. 2). In some embodiments, a bottom surface of the one or more dies is secured to the top insulator of the TFTEC (refer to FIG. 3).

At block 708, a controller, electrically coupled to the one or more dies and the TFTEC, adjusts a thermoelectric device current of the TFTEC responsive to a temperature of the one or more dies.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears. Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A power module comprising:
a direct bond copper (DBC) substrate comprising a top copper layer, a bottom copper layer, and a dielectric layer between the top copper layer and the bottom copper layer;
a thin-film thermoelectric cooler (TFTEC) comprising a thermoelectric film positioned between a top insulator and a bottom insulator;
one or more dies positioned over the DBC substrate and the TFTEC; and
a controller configured to adjust a thermoelectric device current of the TFTEC responsive to a temperature of the one or more dies.

2. The power module of claim 1, further comprising a cold plate coupled to one of the DBC substrate and the TFTEC.

3. The power module of claim 1, wherein the one or more dies each comprise one of an Insulated Gate Bipolar Transistor (IGBT), an anti-parallel diode, a Silicon Carbide (SIC) MOSFET die, a Gallium Nitride (GaN) High Electron Mobility Transistor (HEMT) die, or a vertical GaN Junction Field Effect Transistor (JFET) die.

4. The power module of claim 1, wherein the dielectric layer comprises at least one of a ceramic material, silicon nitride (Si₃N₄), aluminum-oxide (Al₂O₃), and aluminum-nitride (AlN).

5. The power module of claim 1, wherein the thermoelectric film comprises a nano-composite thermoelectric film comprising Bi₂Te₃.

6. The power module of claim 1, wherein a bottom surface of the one or more dies is secured to the top copper layer of the DBC substrate.

7. The power module of claim 1, wherein a bottom surface of the one or more dies is secured to the top insulator of the TFTEC.

8. A vehicle comprising:
an electric motor; and
a power module coupled to the electric motor, the power module comprising:
a direct bond copper (DBC) substrate comprising a top copper layer, a bottom copper layer, and a dielectric layer between the top copper layer and the bottom copper layer;
a thin-film thermoelectric cooler (TFTEC) comprising a thermoelectric film positioned between a top insulator and a bottom insulator;
one or more dies positioned over the DBC substrate and the TFTEC; and
a controller configured to adjust a thermoelectric device current of the TFTEC responsive to a temperature of the one or more dies.

9. The vehicle of claim 8, further comprising a cold plate coupled to one of the DBC substrate and the TFTEC.

10. The vehicle of claim 8, wherein the one or more dies each comprise one of an Insulated Gate Bipolar Transistor (IGBT), an anti-parallel diode, a Silicon Carbide (SiC) MOSFET die, a Gallium Nitride (GaN) High Electron Mobility Transistor (HEMT) die, or a vertical GaN Junction Field Effect Transistor (JFET) die.

11. The vehicle of claim 8, wherein the dielectric layer comprises at least one of a ceramic material, silicon nitride (Si₃N₄), aluminum-oxide (Al₂O₃), and aluminum-nitride (AlN).

12. The vehicle of claim 8, wherein the thermoelectric film comprises a nano-composite thermoelectric film comprising Bi₂Te₃.

13. The vehicle of claim 8, wherein a bottom surface of the one or more dies is secured to the top copper layer of the DBC substrate.

14. The vehicle of claim 8, wherein a bottom surface of the one or more dies is secured to the top insulator of the TFTEC.

15. A method comprising:
forming a direct bond copper (DBC) substrate comprising a top copper layer, a bottom copper layer, and a dielectric layer between the top copper layer and the bottom copper layer;
forming a thin-film thermoelectric cooler (TFTEC) comprising a thermoelectric film positioned between a top insulator and a bottom insulator;
positioning one or more dies over the DBC substrate and the TFTEC; and
adjusting, using a controller electrically coupled to the one or more dies and the TFTEC, a thermoelectric device current of the TFTEC responsive to a temperature of the one or more dies.

16. The method of claim 15, wherein the one or more dies each comprise one of an Insulated Gate Bipolar Transistor (IGBT), an anti-parallel diode, a Silicon Carbide (SIC) MOSFET die, a Gallium Nitride (GaN) High Electron Mobility Transistor (HEMT) die, or a vertical GaN Junction Field Effect Transistor (JFET) die.

17. The method of claim 15, wherein the dielectric layer comprises at least one of a ceramic material, silicon nitride (Si₃N₄), aluminum-oxide (Al₂O₃), and aluminum-nitride (AlN).

18. The method of claim 15, wherein the thermoelectric film comprises a nano-composite thermoelectric film comprising Bi₂Te₃.

19. The method of claim 15, wherein a bottom surface of the one or more dies is secured to the top copper layer of the DBC substrate.

20. The method of claim 15, wherein a bottom surface of the one or more dies is secured to the top insulator of the TFTEC.
